(19) United States
(12) Patent Application Publication
(10) Pub. No.: US 2013/0015457 A1
(43) Pub. Date: Jan. 17, 2013

(54) ORGANIC LIGHT EMITTING DISPLAY DEVICE AND METHOD OF MANUFACTURING THE SAME

(71) Applicant: Chun-Gi You, Yongin-city (KR)

(72) Inventor: Chun-Gi You, Yongin-city (KR)

(21) Appl. No.: 13/310,560

(22) Filed: Dec. 2, 2011

(30) Foreign Application Priority Data
Jul. 11, 2011 (KR) 10-2011-0068551

(51) Int. Cl. H01L 33/16; H01L 29/786

(52) U.S. Cl. 257/71; 438/34; 257/E33.003; 257/E29.273

(57) ABSTRACT

An organic light-emitting display device and a method of manufacturing the same. The organic light-emitting display device includes: a thin-film transistor including an active layer, a gate electrode comprising a first electrode and a second electrode on the first electrode, and source and drain electrodes; an organic light-emitting device including a pixel electrode electrically connected to the thin-film transistor and including nano-Ag, an intermediate layer comprising a light-emitting layer, and an opposite electrode covering the intermediate layer and facing the pixel electrode; and a pad electrode formed on the same plane as and formed of the same material as the first electrode in a pad area outside of a light-emitting area.

### CROSS-REFERENCE TO RELATED PATENT APPLICATION

This application claims priority to and the benefit of Korean Patent Application No. 10-2011-0068551, filed on Jul. 11, 2011, in the Korean Intellectual Property Office, the disclosure of which is incorporated herein in its entirety by reference.

### BACKGROUND

1. Field

The following description relates to an organic light emitting display device and a method of manufacturing the same, and more particularly, to an organic light emitting display device in which a manufacturing process is simplified, and damage of a pad electrode is reduced or minimized, and a method of manufacturing the same.

2. Description of Related Art

Flat panel display devices such as organic light emitting display devices or liquid crystal display devices are each manufactured on a substrate in which a pattern including a thin-film transistor TFT, a capacitor, and a wiring connecting the thin-film transistor TFT and the capacitor is formed.

Generally, in order to form a pattern having a fine structure including a thin-film transistor TFT on a substrate on which a flat panel display device is manufactured, the pattern is transferred onto the substrate by using a mask having the pattern of the fine structure.

A photo-lithography process is generally used to transfer a pattern by using a mask. In the photolithography process, a photoresist is uniformly coated on a substrate in which a pattern is to be formed, the photoresist is exposed by using exposure equipment such as a stepper, and then, (in the case of a positive photoresist) the exposed photoresist is developed. Also, after developing the photoresist, a series of processes of etching the pattern by using the remaining photoresist as a mask and removing unnecessary photoresist, are performed.

The process of transferring the pattern by using the mask, needs a mask including a necessary pattern in advance. Thus, as the number of processes that use masks increases, manufacturing cost for preparing masks increase. In addition, the above-described processes involve many manufacturing complexities, which increase manufacturing time and accordingly increase manufacturing cost.

### SUMMARY

Aspects of embodiments of the present invention are directed toward an organic light-emitting display device that is capable of being manufactured with reduced number of patterning processes, and capable of achieving excellent display quality, and a method of manufacturing the same.

According to an embodiment of the present invention, there is provided an organic light-emitting display device including: a thin-film transistor comprising an active layer, a gate electrode comprising a first electrode and a second electrode on the first electrode, and source and drain electrodes; an organic light-emitting device comprising a pixel electrode electrically connected to the thin-film transistor and including nano-Ag, an intermediate layer comprising a light-emitting layer, and an opposite electrode covering the intermediate layer and facing the pixel electrode; and a pad electrode formed on the same plane as and formed of the same material as the first electrode in a pad area outside of a light-emitting area.

The organic light-emitting display device may further include: a capacitor, the capacitor including a lower electrode formed on the same plane as the active layer and including a semiconductor material doped with impurities, and an upper electrode formed on the same plane as and formed of the same material as the first electrode.

The pixel electrode may be a conductive layer formed of a transparent conductive material including the nano-Ag, and may include a nano-Ag thin-film including the nano-Ag and a conductive layer formed of a transparent conductive material on the nano-Ag thin-film.

The second electrode may be formed as a multiple layer electrode.

The first electrode may be formed of a material different from that of the second electrode, and the first electrode and the second electrode may have a stepped difference.

A top surface of the pixel electrode may be electrically connected to one of the source and drain electrodes.

One of the source and drain electrodes may contact a top portion of the pixel electrode, and another one of the source and drain electrodes may contact a conductive layer that is formed on the same plane as and formed of the same material as the pixel electrode and that is patterned when the source and drain electrodes are formed.

The pad electrode may be electrically connected to a driver IC that supplies a current for driving the organic light-emitting display device.

According to another embodiment of the present invention, there is provided a method of manufacturing an organic light-emitting display device, the method including: performing a first mask process for forming an active layer of a thin-film transistor and a lower electrode of a capacitor; performing a second mask process for respectively forming a gate electrode of the thin-film transistor, an upper electrode of the capacitor, and a pad electrode of the pad area on the active layer and the lower electrode; forming a second insulating layer and a nano-Ag thin-film on the upper electrode of the capacitor and the pad electrode; performing a third mask process for forming an interlayer insulating layer having openings that expose both sides of the active layer; performing a fourth mask process for respectively forming source and drain electrodes that respectively contact the exposed both sides of the active layer and the pixel electrode; and performing a fifth mask process for forming a pixel defining layer that exposes the pixel electrode.

The performing of the first mask process may include: forming a semiconductor layer on a substrate; and forming the active layer of the thin-film transistor and the lower electrode of the capacitor by patterning the semiconductor layer.

The performing of the second mask process may include: sequentially forming a first insulating layer, a first conductive layer, and a second conductive layer on the substrate in which the active layer and the lower electrode of the capacitor are formed; forming a gate electrode that uses the first conductive layer and the second conductive layer as a first electrode and a second electrode of the gate electrode, respectively, by patterning the first conductive layer and the second conductive layer; and respectively forming the upper electrode of the capacitor and the pad electrode by removing the second conductive layer.

The method may further include: doping the both sides of the active layer and the lower electrode of the capacitor after performing the second mask process.

The first conductive layer may be formed of a material different from that of the second conductive layer.

The second mask may be a half-tone mask.

The performing of the second mask process may include: forming the gate electrode having the first conductive layer and the second conductive layer as the first electrode and the second electrode of the gate electrode, respectively, a first electrode pattern for forming the upper electrode of the capacitor by sequentially etching the second conductive layer and the first conductive layer, and a second electrode pattern for forming the pad electrode by sequentially etching the second conductive layer and the first conductive layer; and forming the upper electrode of the capacitor and the pad electrode by etching the second conductive layer of the first electrode pattern and the second conductive layer of the second electrode pattern.

The second electrode may be formed as a multiple layer electrode.

The forming of the nano-Ag thin-film may include: forming an Ag thin-film on the first insulating layer; and forming the nano-Ag thin-film by annealing the Ag thin-film.

The performing of the third mask process may include: forming a third conductive layer on the nano-Ag thin-film; and forming openings that expose the both sides of the active layer and the pad electrode by patterning the second insulating layer, the nano-Ag thin-film, and the third conductive layer.

The third conductive layer may be formed of a transparent conductive layer, and pores of the nano-Ag thin-film may be filled with the third conductive layer.

The performing of the fourth mask process may include: forming a fourth conductive layer on the third conductive layer; and forming the source and drain electrodes and the pixel electrode by patterning the nano-Ag thin-film, the third conductive layer, and the fourth conductive layer.

The performing of the fifth mask process may include: forming a third insulating layer on an entire surface of a substrate; and forming a pixel defining layer by patterning the third insulating layer.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic plan view of a structure of an organic light-emitting display device according to an embodiment of the present invention;

FIG. 2 is a cross-sectional view of a light-emitting area and a pad area which is a non-light-emitting area of the organic light-emitting display device of FIG. 1;

FIGS. 3 through 12 are schematic cross-sectional views showing a method of manufacturing the organic light-emitting display device of FIG. 2; and

FIG. 13 shows the formation of nano-Ag according to an embodiment of the present invention.

### DETAILED DESCRIPTION

The present invention will be described more fully with reference to the accompanying drawings, in which exemplary embodiments of the present invention are shown.

In the drawings, like reference numerals denote like elements. In describing the present invention, when practical descriptions with respect to related known function and configuration may unnecessarily make the scope of the present invention unclear, the descriptions thereof will be omitted.

In describing drawings for explaining an embodiment of the present invention, the thicknesses of layers and regions are exaggerated for clarity. It will be understood that when an element or layer is referred to as being “on” another element or layer, the element or layer may be directly on the other element or layer; or may be on one or more intervening elements or layers.

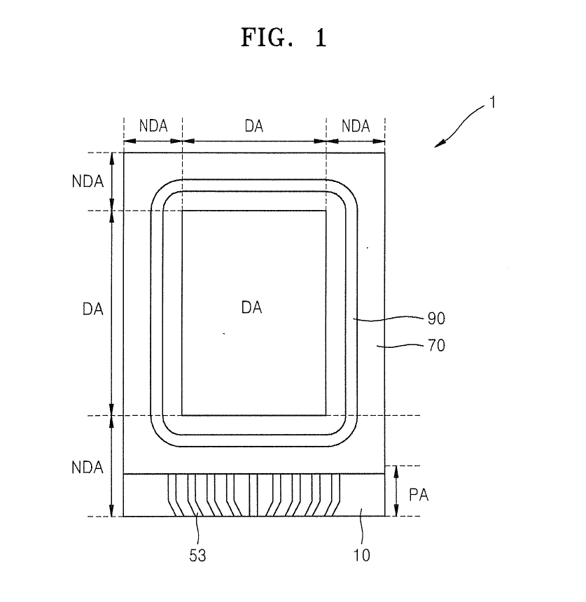

FIG. 1 is a schematic plan view of a structure of an organic light-emitting display device 1 according to an embodiment of the present invention.

The organic light-emitting display device 1 includes a first substrate 10 that includes a thin-film transistor TFT and an organic light-emitting device EL, and a second substrate 70 that is coupled to the first substrate 10 by sealing.

The thin-film transistor TFT, the organic light-emitting device EL, and a capacitor Cst may be formed on the first substrate 10. Also, the first substrate 10 may be a crystalline substrate (LTPS), a glass substrate, or a plastic substrate.

The second substrate 70 may be a sealing substrate disposed on the first substrate 10 to prevent or protect external moisture and air from penetrating into the thin-film transistor TFT and light-emitting pixels disposed on the first substrate 10. The second substrate 70 is disposed to face the first substrate 10, and the first substrate 10 and the second substrate 70 are bonded to each other by a sealing member 90 disposed along edges of the first substrate 10 and the second substrate 70. The second substrate 70 may be a glass substrate, a plastic substrate, or a stainless using steel (SUS) substrate.

The first substrate 10 includes a light-emitting area DA in which light emits and a non-light-emitting area NDA disposed in the boundary of the light-emitting area DA. According to embodiments of the present invention, the first substrate 10 and the second substrate 70 are bonded to each other through the sealing member 90 disposed in the non-light-emitting area NDA disposed in the boundary of the light-emitting area DA.

As described above, the organic light-emitting device EL, the thin-film transistor TFT for driving the organic light-emitting device EL, the capacitor Cst, and a wiring for electrically connecting the organic light-emitting device EL, the thin-film transistor TFT, and the capacitor Cst, are formed in the light-emitting area DA of the first substrate 10. The non-light-emitting area NDA may include a pad area PA in which a pad electrode 53 extends from the wiring of the light-emitting area DA.

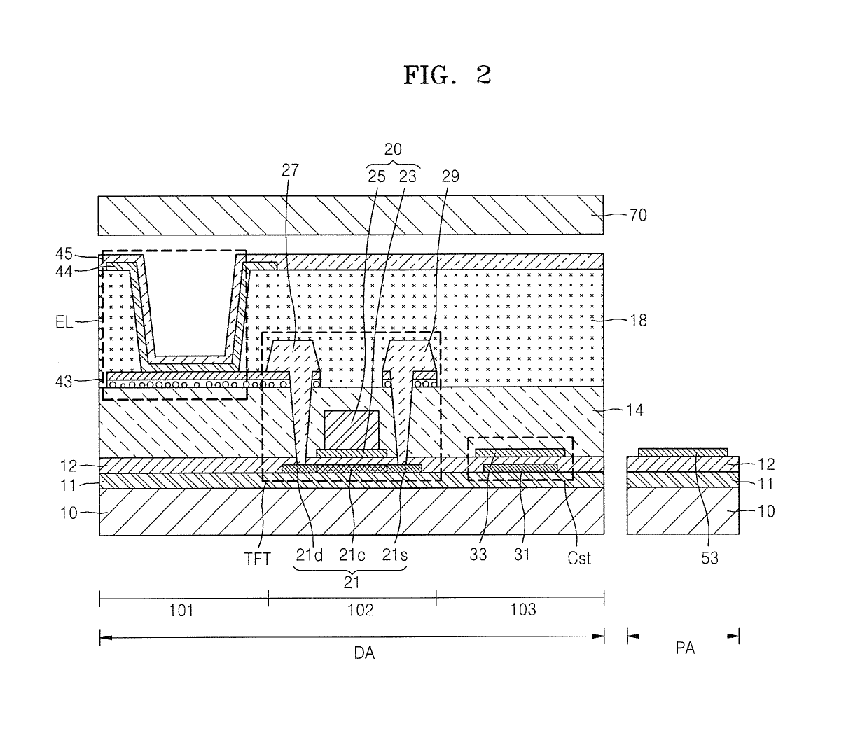

FIG. 2 is a cross-sectional view of the light-emitting area DA and the pad area PA, which is in the non-light-emitting area NDA of the organic light-emitting display device 1 of FIG. 1.

Referring to FIG. 2, the organic light-emitting display device 1 includes a pixel area 101, a channel area 102, a storage area 103, and the pad area PA which are formed on the first substrate 10.

The organic light-emitting device EL is included in the pixel area 101. The organic light-emitting device EL includes a pixel electrode 43 that is connected to one of source and drain electrodes 29 and 27 of the thin-film transistor TFT, an opposite electrode 45 facing the pixel electrode 43, and an intermediate layer 44 interposed between the pixel electrode 43 and the opposite electrode 45. The pixel electrode 43 is formed of a transparent conductive material, and may include nano-sized particle type silver Ag. In FIG. 2, the pixel electrode 43 has a double layer structure in which a nano-Ag thin-film and a conductive layer formed of a transparent conductive material are formed. However, the pixel electrode 43 may have a single layer structure in which pores of the nano-Ag thin-film are filled with the conductive layer formed of the transparent conductive material.

The channel area 102 includes the thin-film transistor TFT as a driving device. The thin-film transistor TFT includes an active layer 21, a gate electrode 20, the source and drain electrodes 29 and 27. The gate electrode 20 includes a first electrode 23 and a second electrode 25 formed on a top portion of the first electrode 23. A first insulating layer 12, which is a gate insulating layer for insulating the gate electrode 20 from the active layer 21, is interposed between the gate electrode 20 and the active layer 21. Also, source/drain areas (portions) 21s and 21d doped with high density impurities are formed in both sides (both edge portions) of the active layer 21, and the source/drain areas 21s and 21d are respectively connected to the source and drain electrodes 29 and 27.

The storage area 103 includes a capacitor Cst. The capacitor Cst includes a lower electrode 31 and an upper electrode 33, and the first insulating layer 12 is interposed between the lower electrode 31 and the upper electrode 33. In this regard, the lower electrode 31 may be formed on the same plane as the active layer 21 of the thin-film transistor TFT. The lower electrode 31 is formed of a semiconductor material, and doped with impurities, which increases electrical conductivity of the lower electrode 31. The upper electrode 33 may be formed on the same plane as and of the same material as the first electrode 23 of the thin-film transistor TFT and the pad electrode 53 of the pad area PA.

The pad area PA includes a pad electrode 53. In this regard, the pad electrode 53 may be formed on the same plane as and of the same material as the first electrode 23 of the thin-film transistor TFT and the upper electrode 33 of the capacitor Cst. The pad electrode 53 is electrically connected to a driver IC that supplies a current for driving the organic light-emitting display device 1. Thus, the pad electrode 53 receives the current from the driver IC and supplies the current to the light-emitting area DA.

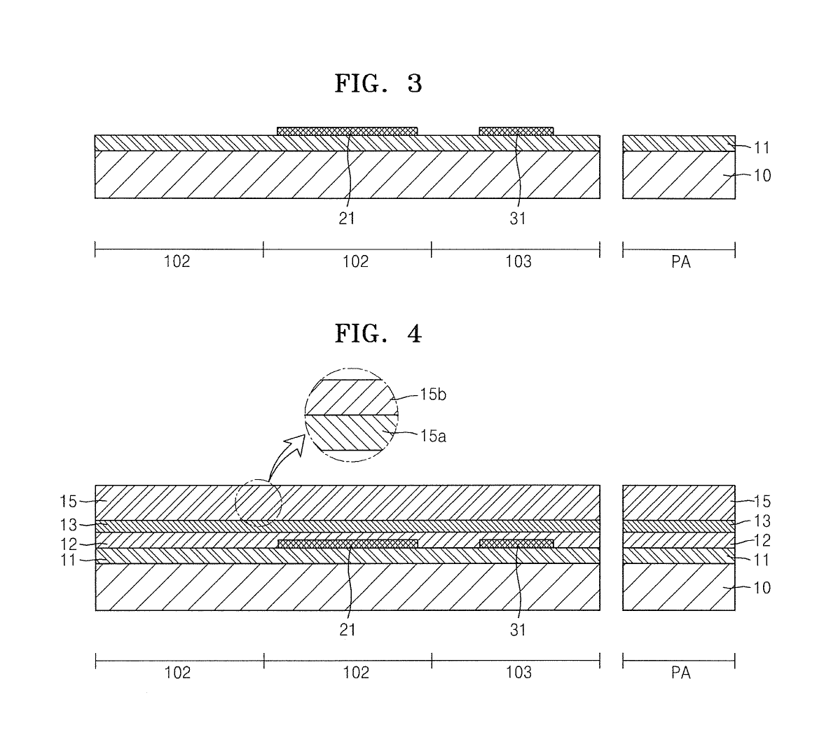

FIGS. 3 through 12 are schematic cross-sectional views showing a method of manufacturing the organic light-emitting display device 1 of FIG. 2. Hereinafter, a process of manufacturing the organic light-emitting display device 1 depicted in FIG. 2 will now be described.

Referring to FIG. 3, an auxiliary layer 11 is formed on a portion of the first substrate 10.

The first substrate 10 may be formed of a transparent glass material having SiO₂ as a main component. The first substrate 10 is not limited thereto, and may be formed of various suitable materials such as a transparent plastic material or a metal material.

The auxiliary layer 11 such as a barrier layer, a blocking layer, and/or a buffer layer for preventing or blocking diffusion of impurity ions and penetration of moisture and air, and for planarizing a surface of the first substrate 10 may be formed on the surface of the first substrate 10. The auxiliary layer 11 may be formed using various suitable deposition methods such as a plasma enhanced chemical vapor deposition (PECVD) method, an atmospheric pressure CVD (APCVD) method, or a low pressure CVD (LPCVD) method using SiO₂ and/or SiNₓ.

The active layer 21 of the thin-film transistor TFT and the lower electrode 31 of the capacitor Cst are formed on a portion of the auxiliary layer 11. More specifically, a polycrystalline silicon layer is formed by depositing an amorphous silicon layer on the auxiliary layer 11 and crystallizing the amorphous silicon layer. The amorphous silicon layer may be crystallized using various crystallization methods, for example, a rapid thermal annealing (RTA) method, a solid phase crystallization (SPC) method, an excimer laser annealing (ELA) method, a metal induced crystallization (MIC) method, a metal induced lateral crystallization (MILC) method, or a sequential lateral solidification (SLS) method. The polycrystalline silicon layer is patterned as the active layer 21 of the thin-film transistor TFT and the lower electrode 31 of the capacitor Cst by using a mask process that uses a first mask.

In the present embodiment, the active layer 21 of the thin-film transistor TFT and the lower electrode 31 of the capacitor Cst are separated from each other. However, the active layer 21 of the thin-film transistor TFT and the lower electrode 31 of the capacitor Cst may be integrally formed.

Referring to FIG. 4, the first insulating layer 12, a first conductive layer 13, and a second conductive layer 15 are sequentially formed on the first substrate 10 in which the active layer 21 of the thin-film transistor TFT and the lower electrode 31 of the capacitor Cst are formed.

The first insulating layer 12 may deposit an inorganic insulating layer such as SiNx or SiOx using a PECVD method, an APCVD method, a LPCVD method, etc. The first insulating layer 12 is disposed between the active layer 21 and the gate electrode 20 of the thin-film transistor TFT, functions as a gate insulating layer of the thin-film transistor TFT, is disposed between the upper electrode 33 and the lower electrode 31 of the capacitor Cst, and functions as a dielectric layer of the capacitor Cst.

The first conductive layer 13 may include at least one material selected from the group consisting of Al, Pt, Pd, Ag, Mg, Au, Ni, Nd, Ir, Cr, Li, Ca, Mo, Ti, W, and Cu. The first conductive layer 13 may be a metal layer including Ti having strong corrosion properties. However, the first conductive layer 13 is not limited thereto, and may be formed of various suitable materials. The first conductive layer 13 may be patterned as the first electrode 23, the upper electrode 33, and the pad electrode 53 of the pad area PA later.

The second conductive layer 15 may include at least one material selected from the group consisting of Al, Pt, Pd, Ag, Mg, Au, Ni, Nd, Ir, Cr, Li, Ca, Mo, Ti, W, and Cu. The second conductive layer 15 may include multilayered metal layers 15a and 15b, and have a two-layer structure of Al—Mo in which the lower Al layer 15a and the upper Mo layer 15b are formed. However, the second conductive layer 15 is not limited thereto, and may be formed to have various suitable layers and of various suitable materials. The second conductive layer 15 may be patterned as the second electrode 25 later.

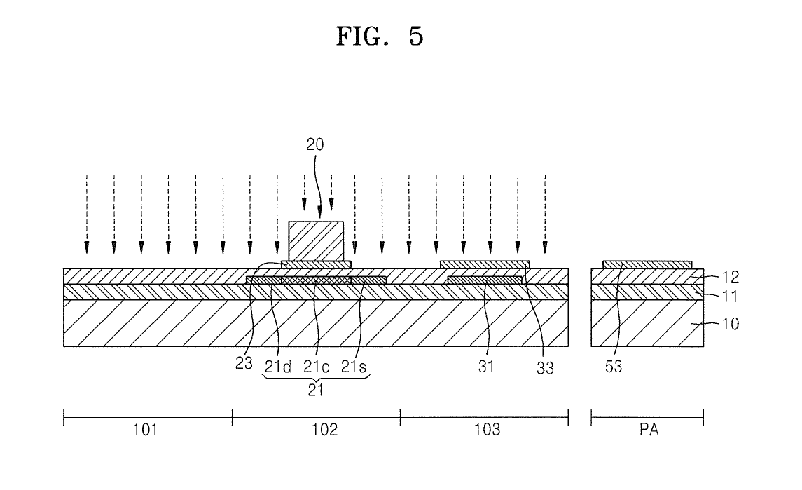

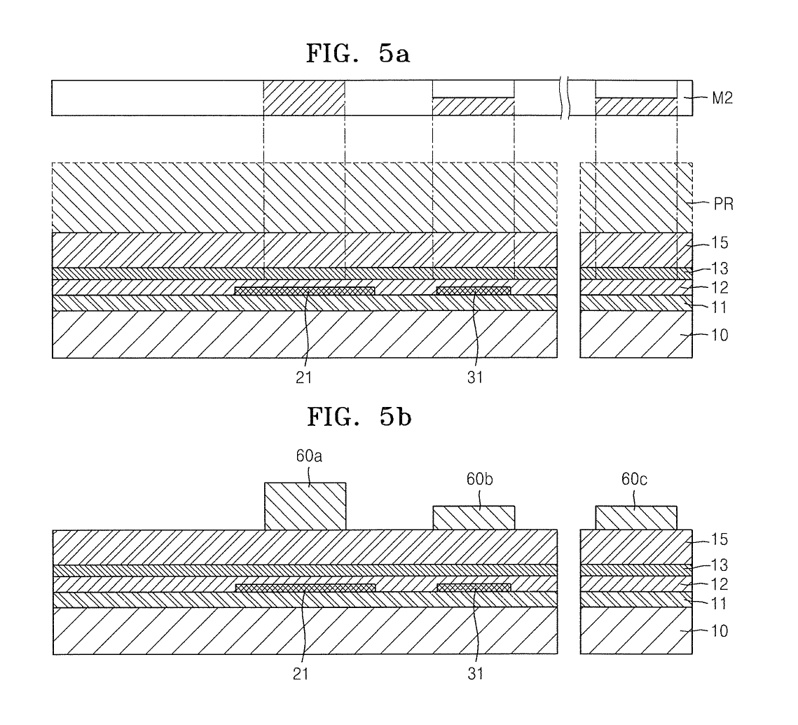

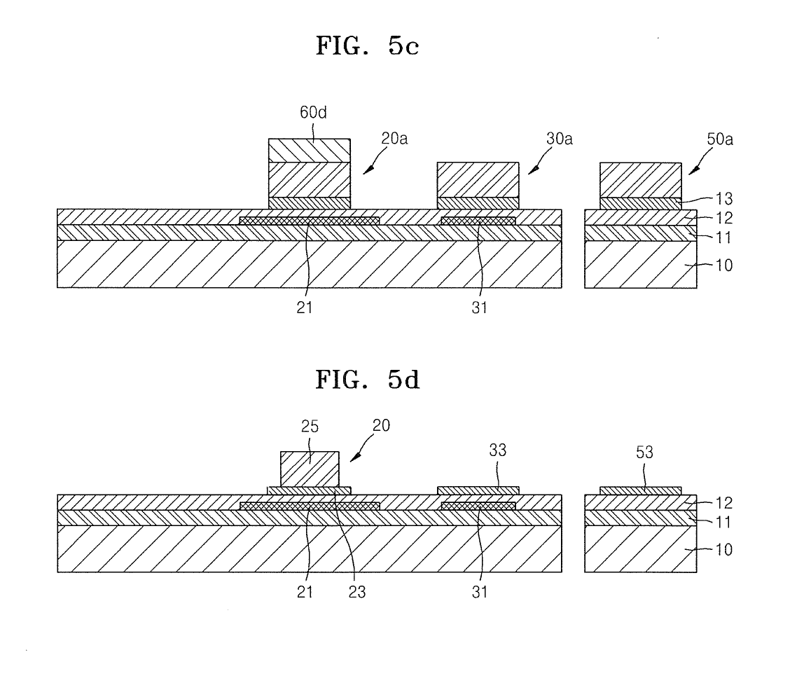

Referring to FIG. 5, the gate electrode 20, the upper electrode 33, and the pad electrode 53 are formed on the first substrate 10. This will be described with reference to FIGS. 5a through 5d.

Referring to FIG. 5a, a photoresist material PR is uniformly coated on the entire surface of the first substrate 10 in which the second conductive layer 15 is deposited as shown in FIG. 4, and a second mask M2 is positioned thereon. The second mask M2 may use a half-tone mask. The photoresist material PR is a photosensitive polymer including a material sensitive to light. The photoresist material PR may include a solvent, a hydrocarbon polymer, and a photoactive compound (PAC). The photoresist material PR may be divided into two types, i.e. a negative type photoresist material PR having a hardened lighted portion and a developed portion, and a positive type photoresist material PR having a dissolved lighted portion. In the present embodiment, the positive type photoresist material PR is coated below.

Referring to FIG. 5b, photoresist patterns 60a, 60b, and 60c are formed by exposing and developing the photoresist material PR using a mask process that uses the second mask M2. In this regard, the second mask M2 is used to form at least the gate electrode 20, the upper electrode 33, and the pad electrode 53, and thus the photoresist patterns 60a, 60b, and 60c remain at least in areas in which the gate electrode 20, the upper electrode 33, and the pad electrode 53 are to be formed. The second mask M2 is the half-tone mask, and thus thicknesses of the photoresist patterns 60b and 60c are approximately (or about) half that of the photoresist pattern 60a.

Referring to FIG. 5c, first wet etching is performed on the second conductive layer 15, dry etching is performed on the first conductive layer 13, and ashing is performed on the storage area 103 and the pad area PA. Thus, a first electrode pattern 20a, a second electrode pattern 30a, and a third electrode pattern 50a are respectively formed in the channel area 102, the storage area 103, and the pad area PA. A photoresist pattern 60d is formed on the first electrode pattern 20a.

Referring to FIG. 5d, second wet etching is performed on a part of the second conductive layer of the second electrode pattern 30a and the third electrode pattern 50a, and ashing is performed on the channel area 102.

Accordingly, the gate electrode 20 is formed on the active layer 21 in the channel area 102, and includes the first electrode 23 formed as a part of the first conductive layer 13 and the second electrode 25 formed as a part of the second conductive layer 15. The gate electrode 20 is formed corresponding to the center of the active layer 21. The upper electrode 33 is formed in a top portion of the lower electrode 23 in the storage area 103. The pad electrode 53 is formed in the pad area PA.

Meanwhile, a side surface of the second conductive layer 15 of the first electrode pattern 20a is partially etched during second wet etching, and thus a stepped difference may be formed between the first electrode 23 and the second electrode 25 of the gate electrode 20.

The first conductive layer 13 and the second conductive layer 15 are formed of different materials with reference to FIGS. 5a through 5d.

Referring to FIG. 5, the gate electrode 20 is used as a self-aligned mask, and the active layer 21 is doped with n-type or p-type impurities to form source and drain areas (portions) 21s and 21d at both sides of the active layer 21 and a channel area 21c interposed therebetween. If portions of the active layer 21 are respectively doped with an III group (a periodic table group III) element such as boron B and a V group (a periodic table group V) element such as nitrogen N, a p-type semiconductor and an n-type semiconductor may be respectively formed. In this regard, doping is performed at the same time so that n-type or p-type impurities are injected into the lower electrode 31, and the lower electrode 31 and the active layer 21 may be concurrently or simultaneously doped.

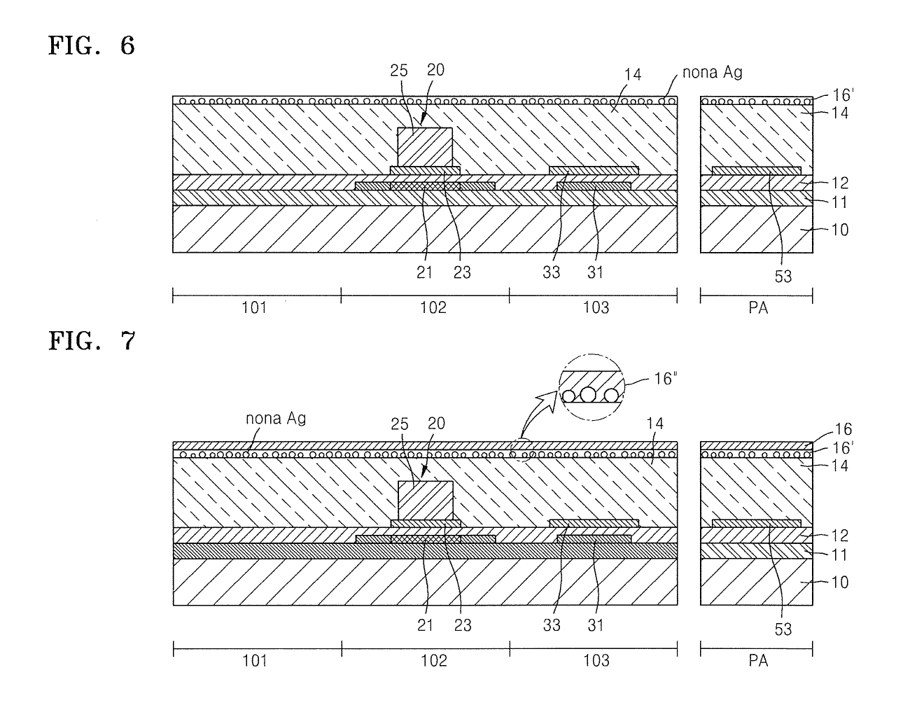

Referring to FIG. 6, a second insulating layer 14 and a nano-Ag thin-film 16′ are deposited on the entire surface of the first substrate 10 in which the gate electrode 20, the upper electrode 33, and the pad electrode 53 are formed.

The second insulating layer 14 is formed of at least one organic insulating material selected from the group consisting of polyimide, polyamide, acryl resin, benzocyclobutene, and phenol resin using a spin coating method. The second insulating layer 14 is formed to have a sufficient thickness, for example, greater than that of the first insulating layer 12, to function as an interlayer insulating layer between the gate electrode 20 of the thin-film transistor TFT and the source and drain electrodes 29 and 27. The second insulating layer 14 may be formed of not only the above-described organic insulating material, but also of an inorganic insulating material like the first insulating layer 12, or by alternately including an organic insulating material and an inorganic insulating material.

In order to realize a metal mirror, the metal characteristics contradictory to the inherent characteristics of a metal of a low absorption rate and a high reflectivity are required. A metal that well satisfies the above characteristics is Ag.

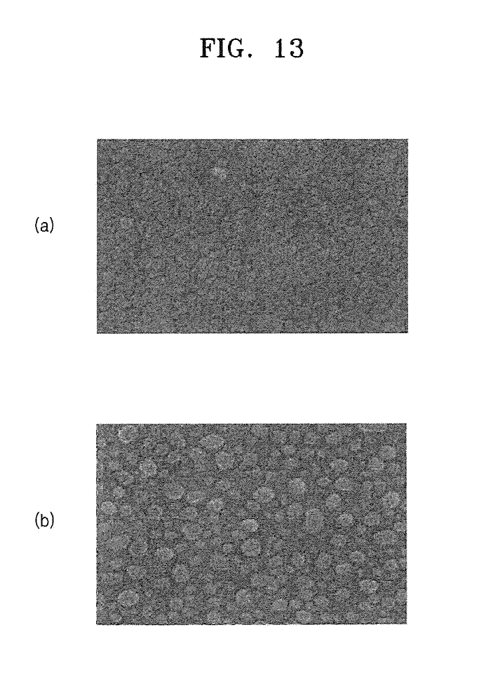

Referring to image (a) of FIG. 13, an Ag thin-film is deposited on a top portion of the second insulating layer 14 by sputtering, and a physical and/or thermal change is applied to the Ag thin-film. For example, an Ag agglomeration phenomenon may occur in the Ag thin-film using the thermal process at about 200° C. Accordingly, referring to image (b) of FIG. 13, the nano-Ag thin-film 16′ in which pores are formed between nano-sized Ag particles (hereinafter, a nano-Ag) may be formed on the top portion of the second insulating layer 14. As another example, the nano-Ag thin-film 16′ may be formed by directly sputtering the nano-Ag on the top portion of the second insulating layer 14. The nano-Ag particles may have different sizes according to processes, and may not be uniform as a whole. The thickness of the nano-Ag thin-film 16′ may be below approximately (or about) 100 Å.

Referring to FIG. 7, a third conductive layer 16 is sequentially deposited on the entire surface of the first substrate 10 in which the second insulating layer 14 and the nano-Ag thin-film 16′ are formed.

The third conductive layer 16 is a transparent conductive layer, and may include at least one selected from the group consisting of indium tin oxide (ITO), indium zinc oxide (IZO), zinc oxide (ZnO), indium oxide (In₂O₃), indium gallium oxide (IGO), and aluminum zinc oxide (AZO).

The present embodiment shows a double layer structure in which the third conductive layer 16 is formed on the top portion of the nano-Ag thin-film 16′. However, as separately shown in FIG. 7, a third conductive layer 16″ of a single layer structure in which pores of the nano-Ag thin-film 16′ are filled with the third conductive layer 16 including nano-Ag may be formed.

The nano-Ag thin-film 16′ and third conductive layer 16 may be patterned later to be the pixel electrode 43.

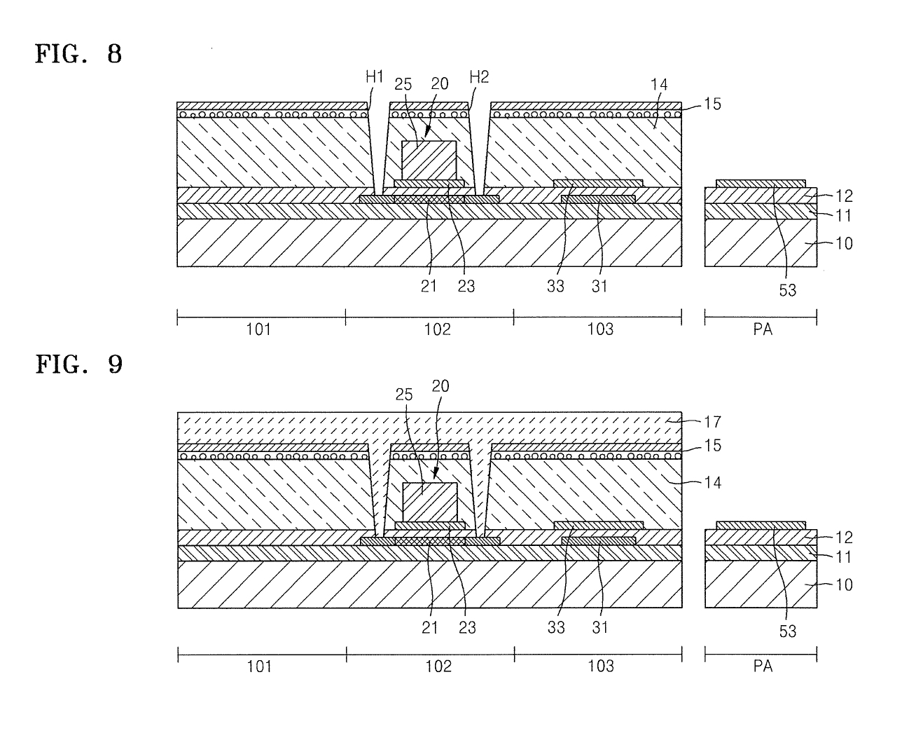

Referring to FIG. 8, the second insulating layer 14, the nano-Ag thin-film 16′, and the third conductive layer 16 are patterned to form first and second openings H1 and H2 that expose portions of the source/drain areas 21s and 21d of the active layer 21.

More specifically, the first and second openings H1 and H2 are formed by patterning the second insulating layer 14 and the third conductive layer 16 using a mask process that uses a third mask. The first and second openings H1 and H2 respectively expose portions of the source/drain areas 21s and 21d.

The pad electrode 53 is exposed by removing the second insulating layer 14, the nano-Ag thin-film 16′, and the third conductive layer 16, that all cover the pad electrode 53 of the pad area PA. In this regard, the pad electrode 53 may be exposed by forming an opening in the second insulating layer 14, the nano-Ag thin-film 16′, and the third conductive layer 16 of the pad area PA.

Referring to FIG. 9, a fourth conductive layer 17 is formed on the entire surface of the first substrate 10 to cover the nano-Ag thin-film 16′ and the third conductive layer 16.

The fourth conductive layer 17 may be formed of the same conductive material used to form the first conductive layer 13 or the second conductive layer 15. However, the present invention is not limited thereto, and the fourth conductive layer 17 may be formed of various suitable conductive materials. Also, the conductive material may be deposited having a sufficient thickness in such a way that the first and second openings H1 and H2 may be filled. In this regard, the fourth conductive layer 17 may not be formed in the pad area PA.

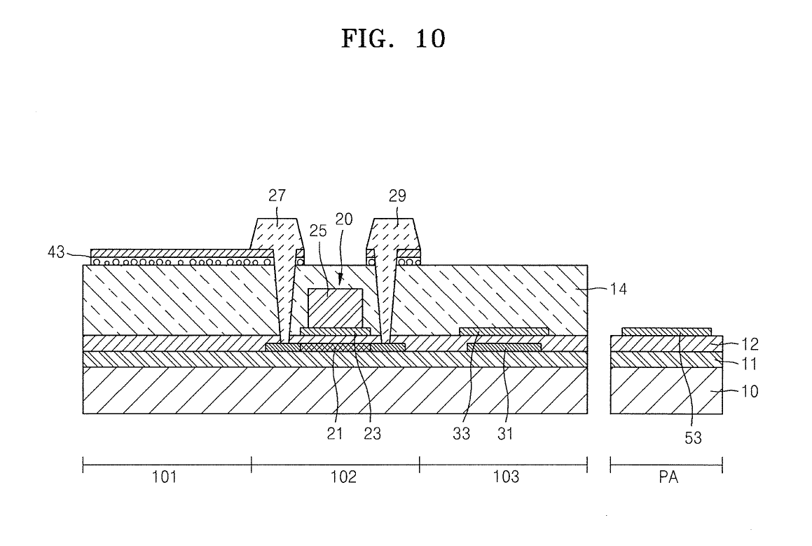

Referring to FIG. 10, the source and the drain electrodes 29 and 27 and the pixel electrode 43 are respectively formed by etching the fourth conductive layer 17.

The source and the drain electrodes 29 and 27 are formed by uniformly coating a photoresist material in the entire surface of the fourth conductive layer 17 using a mask process that uses a fourth mask.

Meanwhile, the pixel electrode 43 is formed concurrently or simultaneously with the formation of the source and the drain electrodes 29 and 27. However, the present invention is not limited thereto, and the pixel electrode 43 may be formed by forming the source and the drain electrodes 29 and 27 and additionally etching the nano-Ag thin-film 16′ and third conductive layer 16.

In this regard, the nano-Ag thin-film 16′ and third conductive layer 16 are etched and removed, excluding portions in which the pixel electrode 43 is to be formed and excluding portions contacting the source and the drain electrodes 29 and 27.

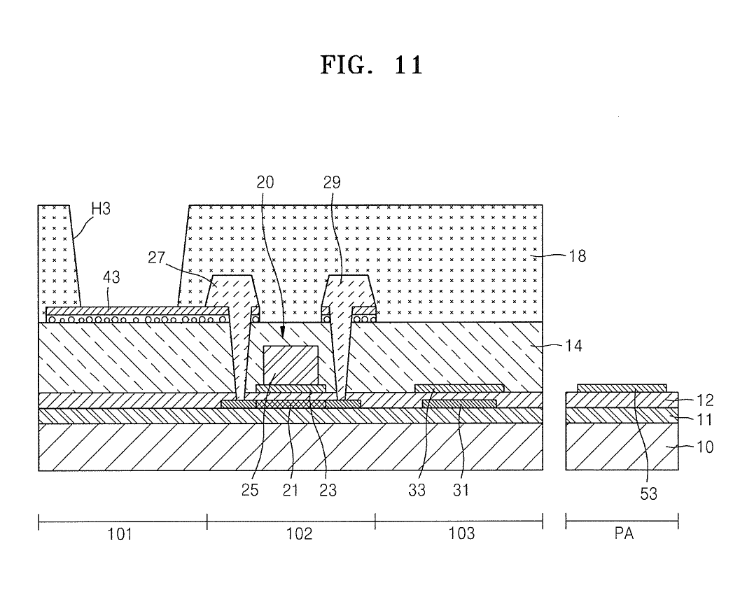

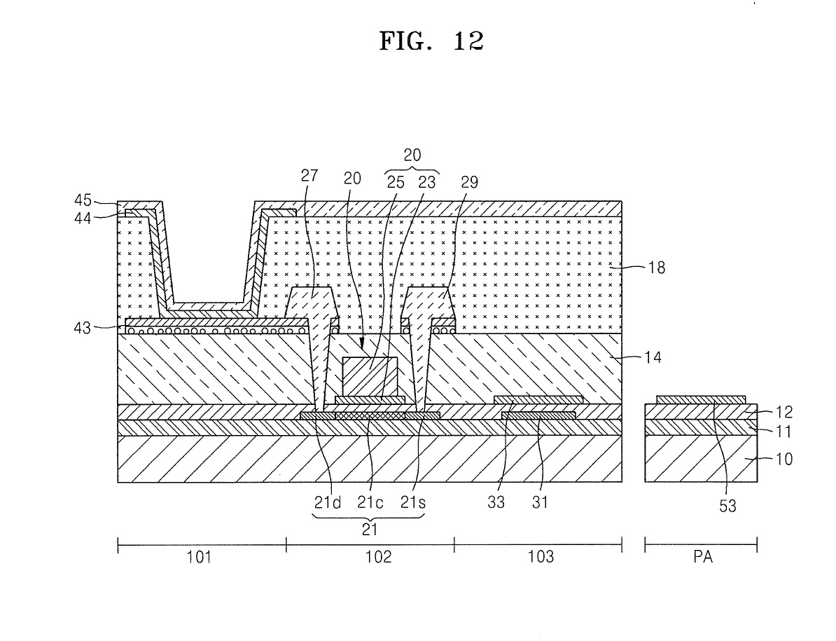

Referring to FIG. 11, a third insulating layer 18 is formed on the first substrate 10.

More specifically, the third insulating layer 18 is deposited to have a sufficient thickness on the entire surface of the first substrate 10 in which the pixel electrode and the source and the drain electrodes 29 and 27 are formed. The third insulating layer 18 may be formed of at least one organic insulating material selected from the group consisting of polyimide, polyamide, acryl resin, benzocyclobutene, and phenol resin using a method such as spin coating. Meanwhile, the third insulating layer 18 may be formed of not only the above-described organic insulation materials, but also of at least one inorganic insulating material selected from the group consisting of SiO₂, SiNₓ, Al₂O₃, CuOx, Tb₄O₇, Y₂O₃, Nb₂O₅, and Pr₂O₃. Also, the third insulating layer 18 may be formed in a multi-layer structure in which an organic insulating material and an inorganic insulating material are alternately formed.

Selectively, the third insulating layer 18 may be deposited on the pad area PA or may not be deposited.

The third insulating layer 18 may be patterned as the PDL by using a mask process in which a fifth mask is used to form a third opening H3 that exposes a center portion of the pixel electrode 43 and thus to define pixels. The opening H3 exposes at least one of four surfaces of the pixel electrode 43 excluding one surface contacting the source and the drain electrodes 29 and 27 in such a way that one surface of the pixel electrode 43 and the PDL do not overlap.

Finally, referring to FIG. 12, the intermediate layer 44 that includes a light emitting layer and the opposite electrode 45 are formed in the third opening H3 that exposes the pixel electrode 43.

The intermediate layer 44 may be formed in a stack structure in which at least one of a plurality of functional layers such as an organic emissive layer (EML), a hole transport layer (HTL), a hole injection layer (HIL), an electron transport layer (ETL), or an electron injection layer (EIL) is stacked in either a single-layer structure or a multi-layer structure.

The intermediate layer 44 may include low-molecular weight organic materials or polymer organic materials.

When the intermediate layer 44 is formed of a low-molecular organic material, the intermediate layer 44 may include an HTL and an HIL around the organic emissive layer in a direction towards the pixel electrode 43, and an ETL and an EIL in a direction towards the opposite electrode 45. Also, other layers may be stacked according to necessity. Non-limiting examples of organic materials include copper phthalocyanine (CuPc), N,N′-Di(naphthalene-1-yl)-N,N′-diphenyl-benzidine (NPB), and tris-8-hydroxyquinoline aluminum (Alq3).

When the intermediate layer 44 is formed of a polymer organic material, the intermediate layer 44 may include only an HTL from the organic emissive layer in a direction toward the pixel electrode 43. The HTL may be formed on the pixel electrode 43 using poly-(2,4)-ethylene-dihydroxy thiophene (PEDOT) and/or polyaniline (PANI) by using an inkjet printing method and/or a spin coating method. Examples of organic materials that may be used here include polymer organic materials such as polyphenylene vinylene (PPV) or polyfluorene; the intermediate layer 44 may be formed by using methods such as an inkjet printing method, a spin coating method, or a laser induced thermal imaging (LITI) method.

The opposite electrode 45 may be deposited on the entire surface of the first substrate 10 as a common electrode. In the organic light-emitting display device 1 according to the current embodiment of the present invention, the pixel electrode 43 is used as an anode and the opposite electrode 45 is used as a cathode. However, the polarities of the electrodes may also be switched.

When the organic light-emitting display device 1 is a bottom emission type display device in which an image is formed in a direction towards the first substrate 10, the pixel electrode 43 may be a transparent electrode and the opposite electrode 45 may be a reflective electrode. The reflective electrode may be formed by depositing a thin layer using a metal having a small work function, such as Ag, Mg, Al, Pt, Pd, Au, Ni, Nd, Ir, Cr, Li, Ca, LiF/Ca, LiF/Al, or a combination of these.

The organic light-emitting display device 1 and a method of manufacturing the organic light-emitting display device 1 according to the present embodiment may be manufactured through five mask processes, and thus manufacturing expense may be reduced owing to a reduction in the number of masks, and manufacturing process may be simplified. Also, the pixel electrode including nano-Ag functions as a metal mirror, and thus it is unnecessary to form an additional layer to function as the metal mirror. Furthermore, a nano-Ag-transparent electrode (ITO) pad is formed in a pad area, and thus a metal such as nano-Ag is not exposed, thereby preventing or reducing corrosion of the pad area.

In each mask process of the method of manufacturing the above-described organic light-emitting display device 1, the stacked layers may be removed using a dry etching method or a wet etching method.

While an organic light-emitting display device has been described as an example, the present invention also applies to other display devices such as a liquid crystal display device.

In addition, while only one TFT and one capacitor are illustrated in the drawings, for convenience of description, the number thereof is not limited thereto. As long as the number of mask processes according to the embodiments of the present invention is not increased, a plurality of TFTs and a plurality of capacitors may be included.

According to an embodiment of the present invention, a process for manufacturing the organic light-emitting display device is simplified, and damage of a pad electrode is minimized or reduced, thereby enhancing the reliability of the organic light-emitting display device.

While the present invention has been particularly shown and described with reference to exemplary embodiments thereof, it will be understood by those of ordinary skill in the art that various changes in form and details may be made therein without departing from the spirit and scope of the present invention as defined by the following claims, and equivalents thereof.

What is claimed is:

1. An organic light-emitting display device comprising:
a thin-film transistor comprising:
an active layer,
a gate electrode comprising a first electrode and a second electrode on the first electrode, and
source and drain electrodes;
an organic light-emitting device comprising:
a pixel electrode electrically connected to the thin-film transistor and comprising nano-Ag,
an intermediate layer comprising a light-emitting layer, and
an opposite electrode covering the intermediate layer and facing the pixel electrode; and
a pad electrode formed on the same plane as and formed of the same material as the first electrode in a pad area outside of a light-emitting area.

2. The organic light-emitting display device of claim 1, further comprising a capacitor, the capacitor comprising:
a lower electrode formed on the same plane as the active layer and including a semiconductor material doped with impurities, and
an upper electrode formed on the same plane as and formed of the same material as the first electrode.

3. The organic light-emitting display device of claim 1, wherein the pixel electrode is a conductive layer formed of a transparent conductive material including the nano-Ag.

4. The organic light-emitting display device of claim 1, wherein the pixel electrode comprises:
a nano-Ag thin-film including the nano-Ag, and
a conductive layer formed of a transparent conductive material on the nano-Ag thin-film.

5. The organic light-emitting display device of claim 1, wherein the second electrode is a multiple layer electrode.

6. The organic light-emitting display device of claim 1, wherein the first electrode is formed of a material different from that of the second electrode, and the first electrode and the second electrode have a stepped difference.

7. The organic light-emitting display device of claim 1, wherein a top surface of the pixel electrode is electrically connected to one of the source and drain electrodes.

8. The organic light-emitting display device of claim 1, wherein one of the source and drain electrodes contacts a top portion of the pixel electrode, and another one of the source and drain electrodes contacts a conductive layer that is formed on the same plane as and formed of the same material as the pixel electrode and patterned when the source and drain electrodes are formed.

9. The organic light-emitting display device of claim 1, wherein the pad electrode is electrically connected to a driver IC configured to supply a current for driving the organic light-emitting display device.

10. A method of manufacturing an organic light-emitting display device, the method comprising:
performing a first mask process for forming an active layer of a thin-film transistor and a lower electrode of a capacitor;
performing a second mask process for respectively forming a gate electrode of the thin-film transistor, an upper electrode of the capacitor, and a pad electrode of a pad area on the active layer and the lower electrode;
forming a second insulating layer and a nano-Ag thin-film on the upper electrode of the capacitor and the pad electrode;
performing a third mask process for forming an interlayer insulating layer having openings that expose both sides of the active layer;
performing a fourth mask process for respectively forming source and drain electrodes that respectively contact the exposed both sides of the active layer and a pixel electrode; and
performing a fifth mask process for forming a pixel defining layer that exposes the pixel electrode.

11. The method of claim 10, wherein the performing of the first mask process comprises:
forming a semiconductor layer on a substrate; and
forming the active layer of the thin-film transistor and the lower electrode of the capacitor by patterning the semiconductor layer.

12. The method of claim 10, wherein the performing of the second mask process comprises:
sequentially forming a first insulating layer, a first conductive layer, and a second conductive layer on a substrate in which the active layer and the lower electrode of the capacitor are formed;
forming the gate electrode that uses the first conductive layer and the second conductive layer as a first electrode and a second electrode of the gate electrode, respectively, by patterning the first conductive layer and the second conductive layer; and
respectively forming the upper electrode of the capacitor and the pad electrode by removing the second conductive layer.

13. The method of claim 10, further comprising doping the both sides of the active layer and the lower electrode of the capacitor after performing the second mask process.

14. The method of claim 12, wherein the first conductive layer is formed of a material different from that of the second conductive layer.

15. The method of claim 14, wherein the second mask is a half-tone mask.

16. The method of claim 10, wherein the performing of the second mask process comprises:
forming the gate electrode having a first conductive layer and a second conductive layer as a first electrode and a second electrode of the gate electrode, a first electrode pattern for forming the upper electrode of the capacitor, and a second electrode pattern for forming the pad electrode by sequentially etching the second conductive layer and the first conductive layer; and
forming the upper electrode of the capacitor and the pad electrode by etching the second conductive layer of the first electrode pattern and the second conductive layer of the second electrode pattern.

17. The method of claim 12, wherein the second electrode is formed as a multiple layer electrode.

18. The method of claim 17, wherein the forming of the nano-Ag thin-film comprises:
forming an Ag thin-film on the first insulating layer; and
forming the nano-Ag thin-film by annealing the Ag thin-film.

19. The method of claim 10, wherein the performing of the third mask process comprises:
forming a third conductive layer on the nano-Ag thin-film; and
forming openings that expose the both sides of the active layer and the pad electrode by patterning the second insulating layer, the nano-Ag thin-film, and the third conductive layer.

20. The method of claim 19, wherein the third conductive layer is formed of a transparent conductive layer, and pores of the nano-Ag thin-film are filled with the third conductive layer.

21. The method of claim 10, wherein the performing of the fourth mask process comprises:
forming a fourth conductive layer on a third conductive layer formed on the nano-Ag thin-film; and
forming the source and drain electrodes and the pixel electrode by patterning the nano-Ag thin-film, the third conductive layer, and the fourth conductive layer.

22. The method of claim 10, wherein the performing of the fifth mask process comprises:
forming a third insulating layer on an entire surface of a substrate; and
forming a pixel defining layer by patterning the third insulating layer.
